(19) United States
(12) Patent Application Publication
(10) Pub. No.: US 2025/0169206 A1
(43) Pub. Date: May 22, 2025

(54) BACKSIDE-ILLUMINATED IMAGE SENSOR AND METHOD OF MANUFACTURING SAME

(71) Applicant: DB HiTek Co., Ltd., Bucheon-si (KR)

(72) Inventor: In Guen YEO, Seoul (KR)

(21) Appl. No.: 18/407,790

(22) Filed: Jan. 9, 2024

(30) Foreign Application Priority Data
Nov. 21, 2023 (KR) 10-2023-0161731

(51) Int. Cl. H01L 27/146

(52) U.S. Cl. CPC H10F 39/199; H10F 39/024; H10F 39/8053; H10F 39/8063; H10F 39/811

(57) ABSTRACT

Proposed are a backside-illuminated image sensor and a method of manufacturing the same. More particularly, proposed are a backside-illuminated image sensor and a method of manufacturing the same, in which a plurality of align keys are formed in an epitaxial layer to be spaced apart from each other in the vertical direction, so that an align signal can be smoothly detected by an align key formed at a relatively shallow depth from a back surface of the epitaxial layer during a subsequent process.

### CROSS-REFERENCE TO RELATED APPLICATION

The present application claims priority to Korean Patent Application No. 10-2023-0161731, filed Nov. 21, 2023, the entire contents of which are incorporated herein for all purposes by this reference.

### BACKGROUND OF THE INVENTION

### Field of the Invention

The present disclosure relates generally to a backside-illuminated image sensor and a method of manufacturing the same. More particularly, the present disclosure relates to a backside-illuminated image sensor and a method of manufacturing the same, in which a plurality of align keys are formed in an epitaxial layer to be spaced apart from each other in the vertical direction, so that an align signal can be smoothly detected by an align key formed at a relatively shallow depth from a back surface of the epitaxial layer during a subsequent process.

### Description of the Related Art

An image sensor is a device that converts an optical image originating from a subject into an electrical signal. This image sensor is a component of an image-capturing device that generates an image in a mobile phone camera or the like. Image sensors can be classified into a charge coupled device (CCD) image sensor and a complementary metal oxide semiconductor (CMOS) image sensor, depending on manufacturing processes and applications. The CMOS image sensor has been widely used as a general semiconductor chip manufacturing process due to its excellent integration competitiveness, economic feasibility, and ease of connection with peripheral chips.

As one type of CMOS image sensor, there is a backside-illuminated image sensor. The backside-illuminated image sensor has improved light reception efficiency compared to a frontside-illuminated image sensor. The backside-illuminated image sensor is generally manufactured by forming a wiring layer on a front surface of a substrate and forming a color filter layer and a microlens on a back surface of the substrate.

When using light in the NIR wavelength band and/or IR wavelength range for the CMOS image sensor, the reaction of light in the NIR wavelength range and/or IR wavelength range with a silicon substrate is relatively very weak compared to light in the visible wavelength range. For this reason, it is preferable that a photoelectric conversion element composed of a photodiode is formed in a relatively deep area within the substrate from a back surface of the substrate. In other words, in order for light in the NIR wavelength range and/or IR wavelength range to react with the silicon substrate, it is preferable for the photoelectric conversion element to be located as deep as possible from the back surface of the substrate.

FIGS. 1 and 2 are sectional views illustrating the structure of a conventional backside-illuminated image sensor and a manufacturing method thereof. Hereinafter, the structure of the conventional backside-illuminated image sensor and the problems arising therefrom will be described with reference to FIGS. 1 and 2.

Referring to FIG. 1, first, a first epitaxial layer 901a and a second epitaxial layer 901b are formed on a front surface 9011 of a first substrate 901. In addition, a plurality of align keys 910 are formed to extend to a predetermined depth from a front surface to a back surface of the second epitaxial layer 901b.

After forming the align keys 910, referring to FIG. 2, a wiring region 920 is formed on the second epitaxial layer 901b, and the second epitaxial layer 901b is inverted so that the wiring region 920 is located thereunder. Then, the first substrate 901 and the first epitaxial layer 901a are removed. Therefore, the align keys 910 are formed on the front side, which is the deepest side of the second epitaxial layer 901b, within the second epitaxial layer 901b and on the wiring region 920.

Here, when the second epitaxial layer 901b is formed to a predetermined thickness or more, since the align keys 910 are formed at a deep position from the front surface of the second epitaxial layer 901b, a problem arises in that align equipment cannot detect a signal of the align keys 910 during a subsequent process. As a result, there is a limitation in the thickness of the second epitaxial layer 901b, so a photoelectric conversion element 930 also cannot be formed deep from the back surface of the second epitaxial layer 901b.

To overcome the above problems, the inventors of the present disclosure have proposed a novel backside-illuminated image sensor having an improved structure and a method of manufacturing the same, which will be described in detail later.

The foregoing is intended merely to aid in the understanding of the background of the present disclosure, and is not intended to mean that the present disclosure falls within the purview of the related art that is already known to those skilled in the art.

### DOCUMENTS OF RELATED ART

(Patent document 1) Korean Patent No. 10-0660549 “Image sensor and method of manufacturing the same”

### SUMMARY OF THE INVENTION

Accordingly, the present disclosure has been made keeping in mind the above problems occurring in the related art, and an objective of the present disclosure is to provide a backside-illuminated image sensor and a method of manufacturing the same, in which a plurality of align keys are formed in an epitaxial layer to be spaced apart from each other in the vertical direction, so that an align signal can be smoothly detected by an align key formed at a relatively shallow depth from a back surface of the epitaxial layer in a subsequent process.

Another objective of the present disclosure is to provide a backside-illuminated image sensor and a method of manufacturing the same, in which a first align key is formed in a first epitaxial layer, so that a second epitaxial layer is formed relatively thick and thus a photoelectric conversion element can be formed at a relatively deep position from a back surface of the second epitaxial layer, thereby improving light reception efficiency.

Another objective of the present disclosure is to provide a backside-illuminated image sensor and a method of manufacturing the same, in which a first align key is formed, so that an exposure mask can be smoothly aligned in an accurate position in a subsequent process such as a pad opening process.

Another objective of the present disclosure is to provide a backside-illuminated image sensor and a method of manufacturing the same, in which a first align key is formed, so that an exposure mask can be smoothly aligned in an accurate position in a second align key formation process.

Another objective of the present disclosure is to provide a backside-illuminated image sensor and a method of manufacturing the same, in which a first align key is formed to have a back surface that is not at least partially covered by a first epitaxial layer, so that an align signal can be more smoothly detected in a subsequent process.

Another objective of the present disclosure is to provide a backside-illuminated image sensor and a method of manufacturing the same, in which a second align key is formed, so that an exposure mask can be smoothly aligned in an accurate position in a subsequent process such as a wiring region formation process.

Another objective of the present disclosure is to provide a backside-illuminated image sensor and a method of manufacturing the same, in which a third epitaxial layer and a third align key are additionally formed, so that a photoelectric conversion element can be formed at a sufficient depth in the entire epitaxial layer, thereby further improving light reception efficiency.

In order to achieve the above objectives, according to one aspect of the present disclosure, there is provided a backside-illuminated image sensor including: a pixel region; a surrounding region disposed adjacent to the pixel region; an epitaxial layer having a first surface and a second surface, which is disposed opposite to the first surface; a color filter disposed in the pixel region and on the second surface of the epitaxial layer; a planarization layer disposed on the color filter; a lens disposed in the pixel region and on the planarization layer; and a plurality of align keys disposed in the surrounding region and in the epitaxial layer, wherein the plurality of align keys has a plurality of first align keys disposed at a first depth from the second surface of the epitaxial layer and a plurality of second align keys disposed at a second depth from the second surface of the epitaxial layer, and wherein the first depth is different from the second depth.

According to another aspect of the present disclosure, the plurality of first align keys disposed at the first depth and the plurality of second align keys disposed at the second depth may have a same pattern.

According to another aspect of the present disclosure, the plurality of first align keys disposed at the first depth may align with the plurality of second align keys disposed at the second depth along a vertical direction from the first surface to the second surface of the epitaxial layer.

According to another aspect of the present disclosure the plurality of first align keys disposed at the first depth, which is disposed adjacent to the second surface of the epitaxial layer, may be used as an align pattern when forming the plurality of second align keys disposed at the second depth.

According to another aspect of the present disclosure, the backside-illuminated image sensor may further include: a wiring region disposed on the first surface of the epitaxial layer; and a carrier substrate or logic substrate disposed on a first surface of the wiring region.

According to another aspect of the present disclosure, there is provided a backside-illuminated image sensor including: a pixel region; a surrounding region disposed adjacent to the pixel region; an epitaxial layer having a first surface and a second surface, which is disposed opposite to the first surface; a photoelectric converter disposed in the pixel region and in the epitaxial layer; and at least one align key disposed in the epitaxial layer. The epitaxial layer may include: a first epitaxial layer defining an upper side of the epitaxial layer; and a second epitaxial layer disposed on a first surface of the first epitaxial layer. The at least one align key may include: a first align key disposed in the surrounding region and in the first epitaxial layer; and a second align key disposed in the surrounding region and in the second epitaxial layer.

According to another aspect of the present disclosure, the first align key may extend to a predetermined depth from the first surface of the epitaxial layer toward a second surface of the first epitaxial layer.

According to another aspect of the present disclosure, the first align key may include an oxide layer.

According to another aspect of the present disclosure, the second epitaxial layer may have a thickness of 5 to 15 μm.

According to another aspect of the present disclosure, a back surface of the first align key, which is adjacent to the second surface of the epitaxial layer, is at least partially not covered by the first epitaxial layer.

According to another aspect of the present disclosure, the photoelectric converter may be disposed on a first surface of the second epitaxial layer.

According to another aspect of the present disclosure, the epitaxial layer may further include a third epitaxial layer disposed on a first surface of the second epitaxial layer, and the at least one align key may further include a third align key disposed in the third epitaxial layer.

According to another aspect of the present disclosure, the first to third align keys may align with one another along a vertical direction from the first surface to the second surface of the epitaxial layer and have a same pattern.

According to another aspect of the present disclosure, there is provided a method of manufacturing a backside-illuminated image sensor, the method including: forming a first epitaxial layer on a first surface of a first substrate; forming a first align key having a predetermined depth from a first surface of the first epitaxial layer toward a second surface of the first epitaxial layer in a surrounding region; forming a second epitaxial layer on the first surface of the first epitaxial layer; forming a second align key having a predetermined depth from a first surface of the second epitaxial layer toward a second surface of the second epitaxial layer in the surrounding region; forming a photoelectric converter in the second epitaxial layer; and forming a wiring region on the first surface of the second epitaxial layer.

According to another aspect of the present disclosure, the wiring region may be formed by using the second align key as an align pattern of an exposure mask.

According to another aspect of the present disclosure, the method may further include: inverting the first substrate so that the second surface of the first epitaxial layer is placed at a top side; and partially removing the second surface of the first epitaxial layer.

According to another aspect of the present disclosure, the first align key may have a vertical thickness of 2,500 to 4,500 kÅ.

According to another aspect of the present disclosure, the second align key may be formed by using the first align key as an align pattern of an exposure mask.

According to another aspect of the present disclosure, the method may further include: forming a color filter on the second surface of the first epitaxial layer in a pixel region; forming a planarization layer on the color filter; and forming a lens on the planarization layer in the pixel region.

The present disclosure has the following effects by the above configuration.

By forming the plurality of align keys in the epitaxial layer to be spaced apart from each other in the vertical direction, an align signal can be smoothly detected by the align key formed at a relatively shallow depth from the back surface of the epitaxial layer in a subsequent process.

In addition, by forming the first align key in the first epitaxial layer, the second epitaxial layer is formed relatively thick and thus the photoelectric conversion element can be formed at a relatively deep position from the back surface of the second epitaxial layer, thereby improving light reception efficiency.

In addition, by forming the first align key, an exposure mask can be smoothly aligned in an accurate position in a subsequent process such as a pad opening process.

In addition, by forming the first align key, the exposure mask can be smoothly aligned in an accurate position in the second align key formation process.

In addition, by forming the first align key to have the back surface that is at least partially not covered by the first epitaxial layer, an align signal can be more smoothly detected in a subsequent process.

In addition, by forming the second align key, an exposure mask can be smoothly aligned in an accurate position in a subsequent process such as a wiring region formation process.

In addition, by additionally forming the third epitaxial layer and the third align key, the photoelectric conversion element can be formed at a sufficient depth in the entire epitaxial layer, thereby further improving light reception efficiency.

Meanwhile, the effects of the present disclosure are not limited to those mentioned above, and other effects not mentioned above can be clearly understood from the following description.

### BRIEF DESCRIPTION OF THE DRAWINGS

The above and other objectives, features, and other advantages of the present disclosure will be more clearly understood from the following detailed description when taken in conjunction with the accompanying drawings, in which:

FIGS. 1 and 2 are sectional views illustrating the structure of a conventional backside-illuminated image sensor;

FIG. 3 is a sectional view illustrating a backside-illuminated image sensor according to an embodiment of the present disclosure;

FIG. 4 is a sectional view illustrating a backside-illuminated image sensor according to another embodiment of the present disclosure;

FIG. 5 is a sectional view illustrating a backside-illuminated image sensor according to another embodiment of the present disclosure; and

FIGS. 6 to 12 are sectional views illustrating a method of manufacturing a backside-illuminated image sensor according to an embodiment of the present disclosure.

### DETAILED DESCRIPTION OF THE INVENTION

Hereinafter, exemplary embodiments of the present disclosure will be described in detail with reference to the accompanying drawings. The embodiments of the present disclosure can be modified in various forms. Therefore, the scope of the present disclosure should not be construed as being limited to the following embodiments, but should be construed on the basis of the descriptions in the appended claims. The embodiments of the present disclosure are provided for complete disclosure of the present disclosure and to fully convey the scope of the present disclosure to those ordinarily skilled in the art.

While the terms “first”, “second”, etc. may be used herein to describe various items such as various elements, regions and/or parts, these items should not be limited by these terms. These terms are only used to distinguish one element from another element.

When a certain embodiment may be implemented differently, a specific process order may be performed differently from the described order. For example, two consecutively described processes may be performed substantially at the same time or performed in an order opposite to the described order.

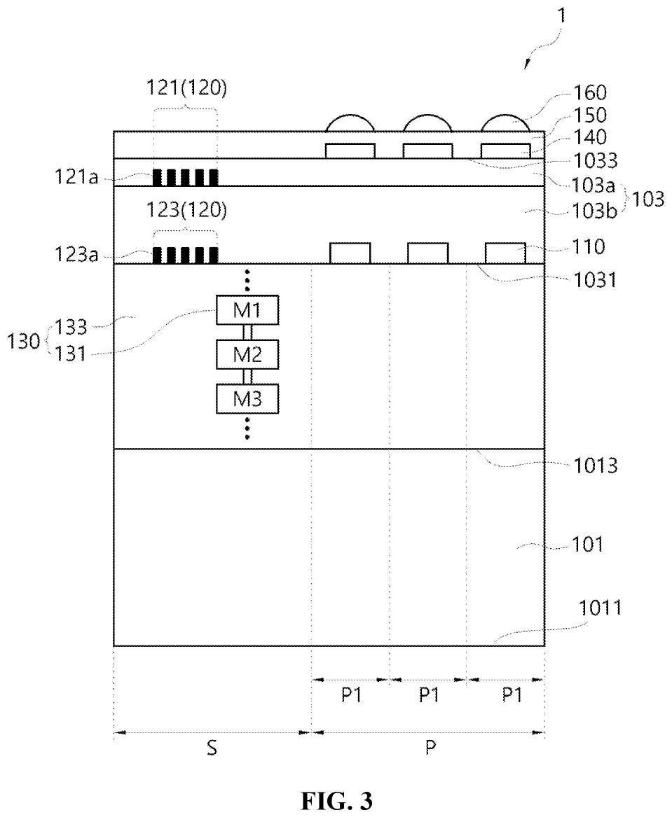

Referring to FIG. 3, a backside-illuminated image sensor 1 according to the present disclosure, a pixel region P and a surrounding region S may be formed. The pixel region P is a region that absorbs light incident from the outside, and the surrounding region S is a region that forms the periphery of the pixel region P. The pixel region P may include a plurality of unit pixel regions P1. In addition, a PAD (not illustrated) may be formed in the surrounding region S for electrical connection to an external terminal.

FIG. 3 is a sectional view illustrating a backside-illuminated image 1 sensor according to an embodiment of the present disclosure.

Hereinafter, the backside-illuminated image sensor 1 according to the embodiment (first embodiment) of the present disclosure will be described in detail with reference to the accompanying drawings.

Referring to FIG. 3, the present disclosure relates to a backside-illuminated image sensor 1. More particularly, the present disclosure relates to a backside-illuminated image sensor 1, in which a plurality of align keys 120 (121 and 123) are formed in an epitaxial layer 103 to be spaced apart from each other in the vertical direction (or at different depths from a back surface 1033 of the epitaxial layer 103), so that an align signal can be smoothly detected by an align key 121 formed at a relatively shallow depth from the back surface 1033 of the epitaxial layer 103 during a subsequent process.

The structure of the backside-illuminated image sensor 1 according to the embodiment of the present disclosure will be described. First, a substrate 101 having a front surface 1011 and a back surface 1013 is formed. In the present disclosure, the substrate 101 may be, for example, a carrier substrate or a logic substrate, and a wiring region 130 and an epitaxial layer 103 may be formed on the back surface 1013 of the substrate 101. The epitaxial layer 103 may have a front surface 1031 and the back surface 1033, and the wiring region 130 may be formed on the front surface 1031. In addition, the epitaxial layer 103 may include a second epitaxial layer 103b and a first epitaxial layer 103a sequentially located on a back surface of the wiring region 130. That is, the first epitaxial layer 103a may be formed on a back surface of the second epitaxial layer 103b. The epitaxial layer 103 may be formed by epitaxial growth. In addition, the first epitaxial layer 103a is preferably formed to have a smaller vertical thickness than the second epitaxial layer 103b. As an example, the second epitaxial layer 103b may be formed to a depth of about 5 to 15 μm, but the present disclosure is not limited thereto.

In addition, a photoelectric conversion element 110 may be formed in the second epitaxial layer 103b. The photoelectric conversion element 110 may be formed in a pixel region P to correspond to each unit pixel region P1. The photoelectric conversion element 110 may be any of various known or to be known elements, such as a photodiode, photogate, or phototransistor. In addition, one or more transistors (not illustrated) electrically connected to the photoelectric conversion element 110 may be formed. The photoelectric conversion element 110 may be formed on a front surface of the second epitaxial layer 103b and at a side adjacent to the front surface. That is, it is preferable that the photoelectric conversion element 110 is formed deep from the back surface 1033 of the epitaxial layer 103. With this configuration, when using light in the NIR wavelength range and/or IR wavelength range, a sufficient reaction of light with a silicon substrate can be induced.

According to the embodiment of the present disclosure, a first align key 121 may be formed in the first epitaxial layer 103a in the surrounding region S. The first align key 121 may extend to a predetermined depth from a front surface to a back surface of the first epitaxial layer 103a. A plurality of first align keys 121 may be formed to be spaced apart from each other in the horizontal direction. The first align keys 121 may be, for example, oxide layers, and may be formed in a shallow trench isolation (STI) structure. However, as another example, they may have a structure formed by gap-filling a conductive material such as metal. In addition, the first align keys 121 may have a vertical thickness of, for example, 2,500 to 4,500 kÅ (Angstrom), but the present disclosure is not limited thereto. To form the first align keys 121, a plurality of individual keys 121a may be formed to be spaced apart from each other in the horizontal direction.

The first align keys 121 may be provided in the same number as a plurality of second align keys 123, which will be described later, and may be spaced apart from the second align keys 123. Each individual key 121a may be formed to vertically overlap each individual key 123a. In more detail, an exposure mask used when forming a plurality of individual keys 123a of the second align keys 123 may be aligned using a pattern of the individual keys 121a of the first align keys 121. Therefore, the first align keys 121 and the second align keys 123 may be formed to vertically overlap each other to have substantially the same pattern. For example, the plurality of individual keys 121a of the first align keys 121 and the plurality of individual keys 123a of the second align keys 123 may be formed in an STI structure and may be spaced apart from each other, respectively, in the horizontal direction.

The first align keys 121 in the first epitaxial layer 103a may correspond to a pattern formed to align an exposure mask to an accurate position in a subsequent process. As an example, the first align keys 121 may be used to align an exposure mask during a pad opening process, but the present disclosure is not limited by the above example. In addition, as described above, the first align keys 121 may be used as a pattern for aligning an exposure mask when forming the second align keys 123.

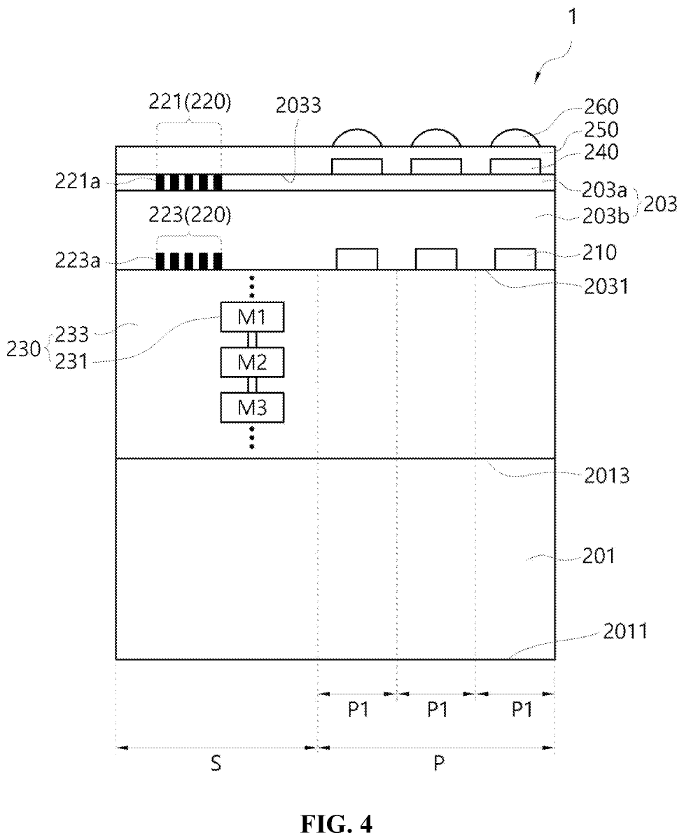

FIG. 4 is a sectional view illustrating a backside-illuminated image 1 sensor according to another embodiment (second embodiment) of the present disclosure.

Referring to FIG. 4, in the other embodiment, a plurality of first align keys 221 may be formed to extend from a front surface to a back surface of a first epitaxial layer 203a. That is, each first align key 221 may be formed to have substantially the same depth as the first epitaxial layer 203a so that a back surface thereof is exposed to a top side in a subsequent process. Alternatively, a back surface of the first align key 221 may have a side that is not at least partially covered by the first epitaxial layer 203a. As described above, when the back surface of the first align key 221 is exposed to the outside in the subsequent process, there is an advantage in that an align signal can be detected more smoothly.

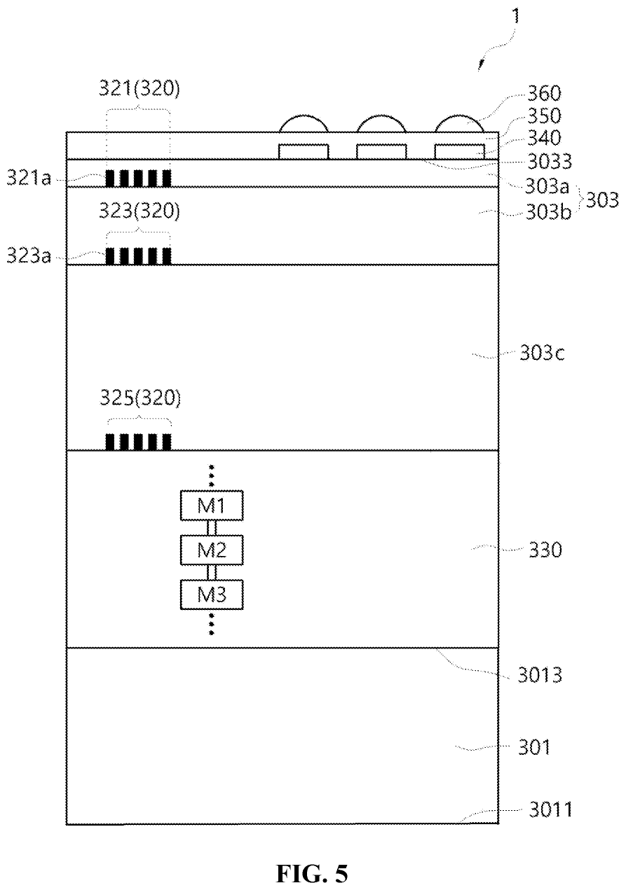

FIG. 5 is a sectional view illustrating a backside-illuminated image 1 sensor according to another embodiment (third embodiment) of the present disclosure.

Referring to FIG. 5, in the other embodiment, after forming additional N (N=natural number) epitaxial layers 303c on a front surface of a second epitaxial layer 303b, a plurality of align keys 325 may be formed to extend to a predetermined depth from a front surface to a back surface of each epitaxial layer 303c. That is, the additional epitaxial layers 303c may be formed between the second epitaxial layer 303b and a wiring region 330. This additional epitaxial layers 303c may be formed by additional epitaxial growth after forming the second epitaxial layer 303b. In addition, a photoelectric conversion element (not illustrated) may be formed in an additional epitaxial layer 303c located directly on the wiring region 330. In FIG. 5, one additional epitaxial layer 303c and the align keys 325 are illustrated, but the present disclosure is not limited thereto.

Referring back to FIG. 3, a second align key 123 may be formed in the second epitaxial layer 103b in the surrounding region S. The second align key 123 may extend to a predetermined depth from a front surface to a back surface of the second epitaxial layer 103b. A plurality of second align keys 123 may be formed to be spaced apart from each other in the horizontal direction. To form the second align keys 123, a plurality of individual keys 123a may be formed to be spaced apart from each other in the horizontal direction. In addition, like the first align keys 121, the second align keys 123 may be, for example, oxide layers, and may be formed in a shallow trench isolation (ST) structure. However, as another example, they may have a structure formed by gap-filling a conductive material such as metal. The second align keys 123 may have a vertical thickness of, for example, 2,500 to 4,500 kÅ (Angstrom), but the present disclosure is not limited thereto. The second align keys 123 may correspond to a pattern formed to align an exposure mask to an accurate position when forming the wiring region 130, which will be described later, before a bonding process. However, the present disclosure is not limited thereto.

Hereinafter, the formation position of an align key 910 of a conventional image sensor 9 and the problems arising therefrom will be described in detail with reference to the accompanying drawings.

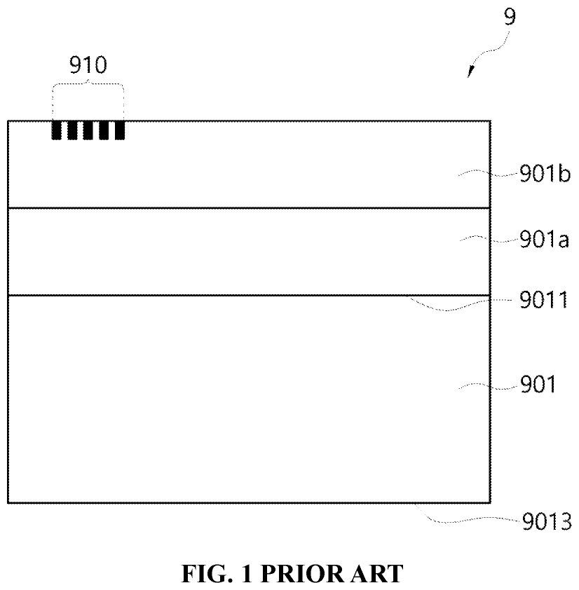

Referring to FIG. 1, first, a first epitaxial layer 901a and a second epitaxial layer 901b are formed on a front surface 9011 of a first substrate 901. In addition, a plurality of align keys 910 are formed to extend to a predetermined depth from a front surface to a back surface of the second epitaxial layer 901b.

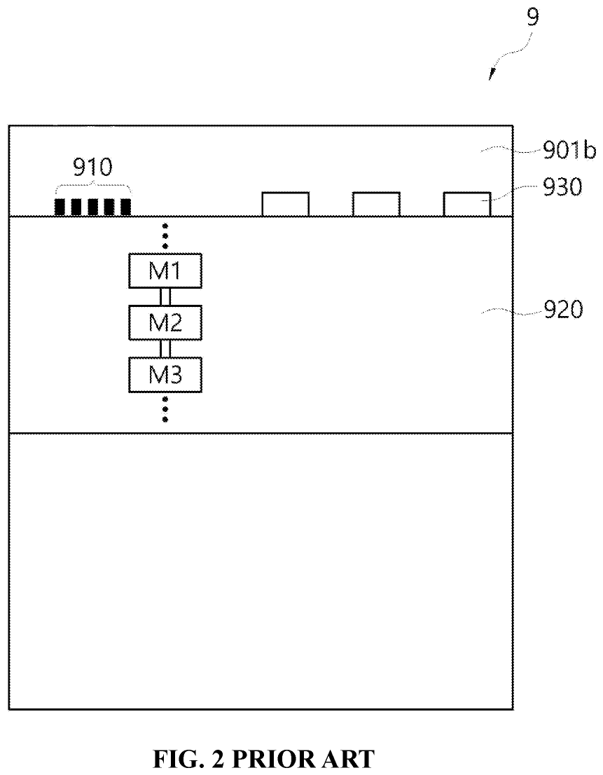

After forming the align keys 910, referring to FIG. 2, a wiring region 920 is formed on the second epitaxial layer 901b, and the second epitaxial layer 901b is inverted so that the wiring region 920 is located thereunder. Then, the first substrate 901 and the first epitaxial layer 901a are removed. Therefore, the align keys 910 are formed on the front side, which is the deepest side of the second epitaxial layer 901b, within the second epitaxial layer 901b and on the wiring region 920.

Here, when the second epitaxial layer 901b is formed to a predetermined thickness or more, since the align keys 910 are formed at a deep position from the front surface of the second epitaxial layer 901b, a problem arises in that align equipment cannot detect a signal of the align keys 910 during a subsequent process. As a result, there is a limitation in the thickness of the second epitaxial layer 901b, so a photoelectric conversion element 930 also cannot be formed deep from the back surface of the second epitaxial layer 901b.

Referring to FIG. 3, in order to solve the above problems, the backside-illuminated image sensor 1 according to the embodiment of the present disclosure is characterized by forming the first align keys 121 spaced upward from the second align keys 123 in the first epitaxial layer 103a. Therefore, due to the first align keys 121 formed separately from the second align keys 123, the overall thickness of the second epitaxial layer 103b is relatively less limited, so the photoelectric conversion element 110 can be formed at a relatively deep position. Consequently, the backside-illuminated image sensor 1 according to the embodiment of the present disclosure can have improved light reception efficiency. In addition, since the first align keys 121 are formed at a relatively shallow depth from the back surface of the first epitaxial layer 103a, a signal of the first align keys 121 can be smoothly detected during a subsequent process.

Next, the wiring region 130 may be formed on the front surface of the second epitaxial layer 103b. The wiring region 130 may include a wiring layer 131 and an insulating layer 133.

The wiring layer 131 may be formed by, for example, a single metal or an alloy layer in which different types of metals are mixed, and preferably includes, for example, an aluminum(Al) layer. In addition, a plurality of wiring layers 131 may be stacked to form a multi-layer structure M1, M2, M3 in the insulating layer 133.

The insulating layer 133 may include an insulating material such as a silicon oxide layer, and may be repeatedly stacked with the wiring layers 131. In addition, one wiring layer 131 may be electrically connected to another adjacent wiring layer 131 through a contact plug. In addition, one wiring layer 131 may be electrically connected to a transistor through a contact plug. The contact plug may be formed in the insulating layer 133 through a damascene process. In order to electrically connect the wiring layers 131 that are vertically stacked, the contact plug may be formed by at least any one conductive material, for example, selected from the group consisting of a polycrystalline silicon layer doped with impurity ions, a metal, and an alloy layer in which different types of metals are mixed.

In addition, the insulating layer 133 may be formed by, for example, any one oxide layer selected from the group consisting of BPSG, PSG, BSG, USG, TEOS, and HDP or a stacked layer in which at least two layers selected from the aforementioned group are mixed. In addition, the insulating layer 133 may be planarized through a CMP process after deposition.

In addition, a color filter part 140 may be formed on the back surface 1033 of the epitaxial layer 103 in the pixel region P. Only a necessary color may be selected by corresponding color filters (red, green, blue) of the color filter part 140 from incident light entering through a lens part 160, which will be described later. The color selected may enter the photoelectric conversion element 110 of a corresponding unit pixel region P1. The formation process of the color filter part 140 will be described. For example, a red color filter may be formed by applying a red photoresist on the back surface 1033 of the epitaxial layer 103 and then exposing and developing it, and a green color filter may be formed by applying a green photoresist on a protective film on which the red color filter is formed and then exposing and developing it. Thereafter, a blue color filter may be formed by applying a blue photoresist and then exposing and developing it. The color filter part 140 may be formed in the pixel region P.

In addition, a planarization layer 150 may be formed on the color filter part 140. The planarization layer 150 may include, for example, a silicon oxide layer.

In addition, the lens part 160 may be formed on the planarization layer 150. The lens part 160 may include a plurality of microlenses that focus light entering the back surface 1033 of the epitaxial layer 103 on the photoelectric conversion element 110 within a corresponding unit pixel region P1. The lens part 160 may be formed in the pixel region P.

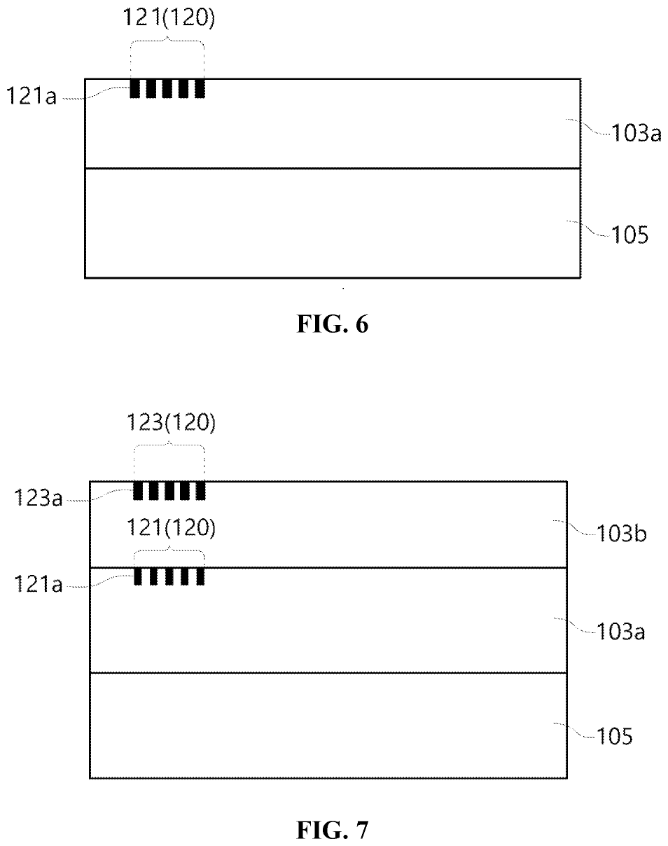

FIGS. 6 to 12 are sectional views illustrating a method of manufacturing a backside-illuminated image sensor according to an embodiment of the present disclosure.

Hereinafter, the method of manufacturing the backside-illuminated image sensor according to the embodiment of the present disclosure will be described in detail with reference to the accompanying drawings.

Referring to FIG. 6, first, a first epitaxial layer 103a may be grown on a front surface of a substrate 105. Thereafter, a plurality of first align keys 121 having a predetermined depth may be formed from a front surface to a back surface of the first epitaxial layer 103a using a mask pattern (not illustrated). As described above, the first align keys 121 may be formed through an STI process. Additionally, the first align keys 121 may be formed to a depth of about 2,500 to 4,500 kÅ (Angstrom) from the front surface of the first epitaxial layer 103b, but the present disclosure is not limited thereto. The first align keys 121 may be formed, for example, by forming trenches by etching the first epitaxial layer 103a using a mask pattern (not illustrated) on the front surface of the first epitaxial layer 103a, and then depositing and removing an oxide layer (not illustrated). In the drawing, it is illustrated that each first align key 121 is gap-filled in the entire inner space of a trench. However, the present disclosure is not limited thereto, and the first align key 121 may be formed to have a substantially uniform thickness along an inner wall of the trench.

Then, referring to FIG. 7, a second epitaxial layer 103b may be grown on a front surface of the first epitaxial layer 103a. Thereafter, a plurality of second align keys 123 having a predetermined depth may be formed from a front surface to a back surface of the second epitaxial layer 103b. Like the first align keys 121, the second align keys 123 may be formed through an STI process and may be formed to a depth of about 2,500 to 4,500 kÅ (Angstrom). In addition, the first align keys 121 may be used as a pattern to align an exposure mask to an accurate position when forming the second align keys 121. Both the first align keys 121 and the second align keys 123 may be formed in a surrounding region S.

The second align keys 123 may be formed, for example, by forming trenches by etching the second epitaxial layer 103b using a mask pattern (not illustrated) on the front surface of the second epitaxial layer 103b, and then depositing and removing an oxide layer (not illustrated). In the drawing, it is illustrated that each second align key 123 is gap-filled in the entire inner space of a trench. However, the present disclosure is not limited thereto, and the second align key 123 may be formed to have a substantially uniform thickness along an inner wall of the trench.

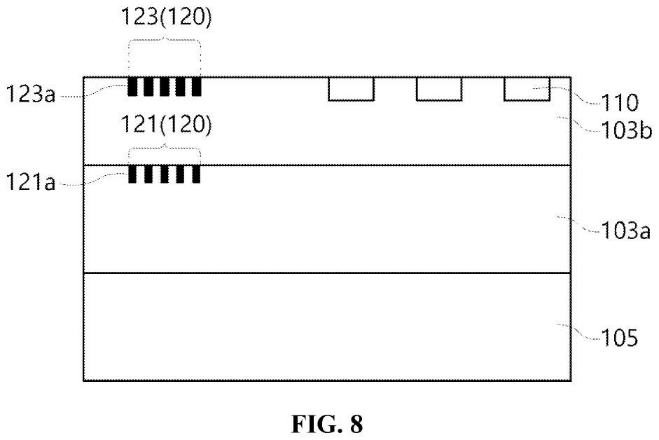

Then, referring to FIG. 8, a photoelectric conversion element 110 may be formed in the second epitaxial layer 103b. The photoelectric conversion element 110 may be formed, for example, by implanting impurities of second conductivity type into an epitaxial layer 103 of first conductivity type. The photoelectric conversion element 110 may be formed in each unit pixel region P1 in a pixel region P.

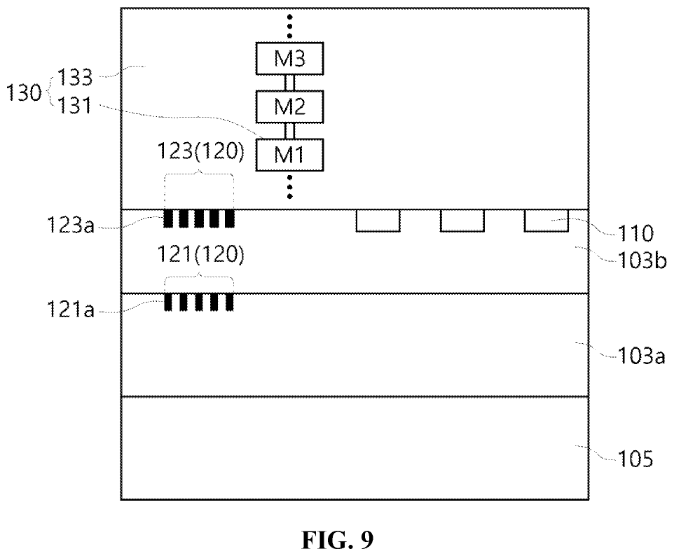

Then, referring to FIG. 9, a wiring region 130 may be formed on the front surface of the second epitaxial layer 103b. The wiring region 130 may be formed by alternately stacking a plurality of wiring layers 131 and an insulating layer 133 with each other. The wiring layers 131 may include, for example, a first metal M1, a second metal M2, and a third metal M3, but the present disclosure is not limited thereto. When forming the wiring region 130, the second align keys 123 may be used as an align pattern.

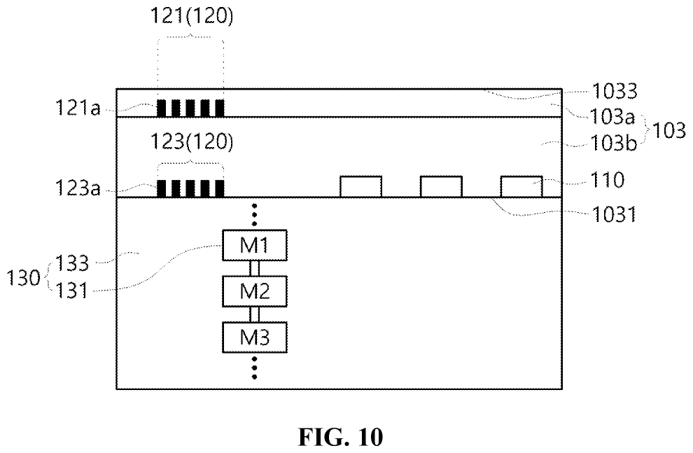

Then, referring to FIG. 10, a front surface of the wiring region 130 may be bonded to a second substrate 101, which is a carrier substrate or logic substrate (not illustrated, see FIG. 3), through a bonding process, and the first substrate 105 and the epitaxial layer 103 may be inverted so that a back surface 1033 of the epitaxial layer 103 is placed at the top side. In addition, a process of removing the first substrate 105 and partially removing the back surface of the first epitaxial layer 103a may be performed. As a result, the thickness of the first epitaxial layer 103a may become thinner, and in some cases, back surfaces of the first align keys 121 may be exposed to the top side. Then, the first align keys 121 may be used as an align pattern for an exposure mask during a subsequent process such as a pad opening process.

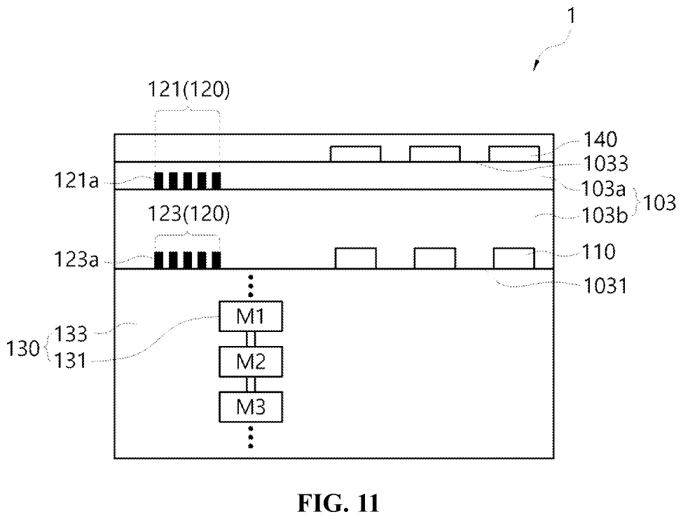

Then, referring to FIG. 11, a color filter part 140 may be formed on the back surface 1033 of the epitaxial layer 103. The color filter part 140 may be formed in the following manner. For example, a red color filter may be formed by applying a red photoresist on the back surface 1033 of the epitaxial layer 103 and then exposing and developing it, and a green color filter may be formed by applying a green photoresist on a protective film on which the red color filter is formed and then exposing and developing it. Thereafter, a blue color filter may be formed by applying a blue photoresist and then exposing and developing it.

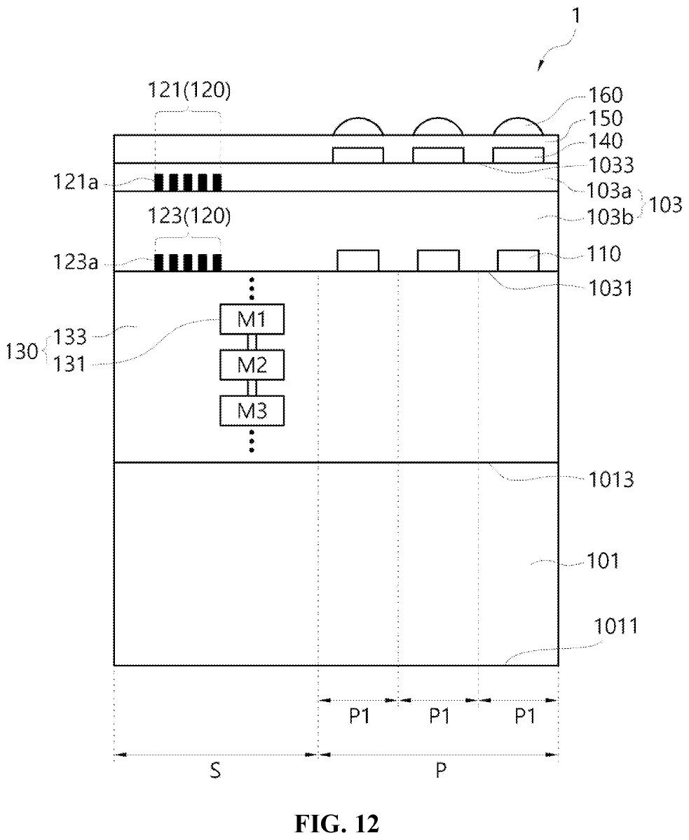

Then, referring to FIG. 12, a planarization layer 150 may be formed on the color filter part 140. The planarization layer 150 may include a silicon oxide layer. Finally, a lens part 160 may be formed on the planarization layer 150. The lens part 160 may include a plurality of microlenses ML.

The foregoing detailed description may be merely an example of the present disclosure. Also, the inventive concept is explained by describing the preferred embodiments and will be used through various combinations, modifications, and environments. That is, the inventive concept may be amended or modified without departing from the scope of the technical idea and/or knowledge in the art. The foregoing embodiments are for illustrating the best mode for implementing the technical idea of the present disclosure, and various modifications may be made therein according to specific application fields and uses of the present disclosure. Therefore, the foregoing detailed description of the present disclosure is not intended to limit the inventive concept to the disclosed embodiments.

What is claimed is:

1. A backside-illuminated image sensor comprising:
a pixel region;
a surrounding region disposed adjacent to the pixel region;
an epitaxial layer having a first surface and a second surface, which is disposed opposite to the first surface;
a color filter disposed in the pixel region and on the second surface of the epitaxial layer;
a planarization layer disposed on the color filter;
a lens disposed in the pixel region and on the planarization layer; and
a plurality of align keys disposed in the surrounding region and in the epitaxial layer,
wherein the plurality of align keys has a plurality of first align keys disposed at a first depth from the second surface of the epitaxial layer and a plurality of second align keys disposed at a second depth from the second surface of the epitaxial layer, and wherein the first depth is different from the second depth.

2. The backside-illuminated image sensor of claim 1, wherein the plurality of first align keys disposed at the first depth and the plurality of second align keys disposed at the second depth have a same pattern.

3. The backside-illuminated image sensor of claim 1, wherein the plurality of first align keys disposed at the first depth aligns with the plurality of second align keys disposed at the second depth along a vertical direction from the first surface to the second surface of the epitaxial layer.

4. The backside-illuminated image sensor of claim 1, wherein the plurality of first align keys disposed at the first depth, which is disposed adjacent to the second surface of the epitaxial layer, is used as an align pattern when forming the plurality of second align keys disposed at the second depth.

5. The backside-illuminated image sensor of claim 1, further comprising:
a wiring region disposed on the first surface of the epitaxial layer; and
a carrier substrate or logic substrate disposed on a first surface of the wiring region.

6. A backside-illuminated image sensor comprising:
a pixel region;
a surrounding region disposed adjacent to the pixel region;
an epitaxial layer having a first surface and a second surface, which is disposed opposite to the first surface;
a photoelectric converter disposed in the pixel region and in the epitaxial layer; and
at least one align key disposed in the epitaxial layer,
wherein the epitaxial layer comprises:
a first epitaxial layer defining an upper side of the epitaxial layer; and
a second epitaxial layer disposed on a first surface of the first epitaxial layer, and wherein the at least one align key comprises:
a first align key disposed in the surrounding region and in the first epitaxial layer; and
a second align key disposed in the surrounding region and in the second epitaxial layer.

7. The backside-illuminated image sensor of claim 6, wherein the first align key extends to a predetermined depth from the first surface of the first epitaxial layer toward a second surface of the first epitaxial layer.

8. The backside-illuminated image sensor of claim 6, wherein the first align key includes an oxide layer.

9. The backside-illuminated image sensor of claim 6, wherein the second epitaxial layer has a thickness of 5 to 15 μm.

10. The backside-illuminated image sensor of claim 6, wherein a back surface of the first align key, which is adjacent to the second surface of the epitaxial layer, is at least partially not covered by the first epitaxial layer.

11. The backside-illuminated image sensor of claim 6, wherein the photoelectric converter is disposed on a first surface of the second epitaxial layer.

12. The backside-illuminated image sensor of claim 6, wherein the epitaxial layer further comprises a third epitaxial layer disposed on a first surface of the second epitaxial layer, and
the at least one align key further comprises a third align key disposed in the third epitaxial layer.

13. The backside-illuminated image sensor of claim 12, wherein the first to third align keys align with one another along a vertical direction from the first surface to the second surface of the epitaxial layer and have a same pattern.

14. A method of manufacturing a backside-illuminated image sensor, the method comprising:
forming a first epitaxial layer on a first surface of a first substrate;
forming a first align key having a predetermined depth from a first surface of the first epitaxial layer toward a second surface of the first epitaxial layer in a surrounding region;
forming a second epitaxial layer on the first surface of the first epitaxial layer;
forming a second align key having a predetermined depth from a first surface of the second epitaxial layer toward a second surface of the second epitaxial layer in the surrounding region;
forming a photoelectric converter in the second epitaxial layer; and
forming a wiring region on the first surface of the second epitaxial layer.

15. The method of claim 14, wherein the wiring region is formed by using the second align key as an align pattern of an exposure mask.

16. The method of claim 14, further comprising:
inverting the first substrate so that the second surface of the first epitaxial layer is placed at a top side; and
partially removing the second surface of the first epitaxial layer.

17. The method of claim 14, wherein the first align key has a vertical thickness of 2,500 to 4,500 kÅ.

18. The method of claim 14, wherein the second align key is formed by using the first align key as an align pattern of an exposure mask.

19. The method of claim 16, further comprising:
forming a color filter on the second surface of the first epitaxial layer in a pixel region;
forming a planarization layer on the color filter; and
forming a lens on the planarization layer in the pixel region.
